(19) United States
(12) Patent Application Publication
(10) Pub. No.: US 2011/0155214 A1
(43) Pub. Date: Jun. 30, 2011

(54) PHOTOVOLTAIC MODULE HAVING THERMOELECTRIC COOLING MODULE

(75) Inventor: Hi-Ki LAM, Hong Kong (HK)

(73) Assignee: Du Pont Apollo Limited, Hong Kong (HK)

(21) Appl. No.: 12/979,389

(22) Filed: Dec. 28, 2010

Related U.S. Application Data
(60) Provisional application No. 61/291,487, filed on Dec. 31, 2009.

(51) Int. Cl. H01L 31/052

(52) U.S. Cl. 136/246

(57) ABSTRACT

A photovoltaic module is described. The photovoltaic module includes a supporting frame, a photovoltaic panel fixed on the supporting frame, and a thermoelectric module fixed on the photovoltaic panel to reduce an operating temperature of the photovoltaic panel. The photovoltaic module can use a heat sink to reduce the operating temperature of the photovoltaic panel. The heat sink is an additional heat sink or the supporting frame that can function as a heat sink to increase the temperature gradient for the thermoelectric module.

### RELATED APPLICATIONS

This application claims priority to U.S. Provisional Application Ser. No. 61/291,487, filed Dec. 31, 2009, which is herein incorporated by reference.

### FIELD OF THE INVENTION

The present invention generally relates to a photovoltaic module. More particularly, this invention relates to a photovoltaic module having a thermoelectric cooling module.

### BACKGROUND OF THE INVENTION

The increasing scarcity and the realization of the ecological and safety problems associated with non-renewable energy resources such as coal, petroleum and uranium, have made it essential that increased use be made of alternate non-depletable energy resources such as solar energy. Solar energy use has been limited in the past to special applications due in part to the high cost of manufacturing devices capable of producing significant amounts of photovoltaic energy. The improvement in manufacturing technology for fabricating the solar panel in mass production has greatly promoted the use of solar energy.

Significant environmental benefits are also realized from solar energy production, for example, reduction in air pollution from burning fossil fuels, reduction in water and land use from power generation plants, and reduction in the storage of waste byproducts. Solar energy produces no noise, and has few moving components. Because of their reliability, solar panels also reduce the cost of residential and commercial power to consumers.

The efficiency of the amorphous silicon thin film for solar panels is around 7%. The remaining solar energy is transferred into waste heat which does not include electrical energy generation. Therefore, there is a need to improve the conversion efficiency of the photovoltaic module.

### SUMMARY OF THE INVENTION

One objective of the present invention is to provide a thermoelectric module for a photovoltaic module to reduce the operating temperature of the photovoltaic module and improve the photoelectric conversion efficiency of the photovoltaic module.

To achieve these and other advantages and in accordance with the objective of the present invention, as the embodiment broadly describes herein, the present invention provides a photovoltaic module. The photovoltaic module includes a supporting frame, a photovoltaic panel fixed on the supporting frame, and a thermoelectric module fixed on the photovoltaic panel to reduce an operating temperature of the photovoltaic panel. The photovoltaic module includes a heat sink to be fixed on the thermoelectric module. Alternatively, the supporting frame functions as a heat sink and the thermoelectric module is fixed to the supporting frame. The hot side of the thermoelectric module is coupled to the photovoltaic panel and the cold side of the thermoelectric module is coupled to the heat sink. Preferably, the heat sink includes a conducting plate to couple to the cold side of the thermoelectric module and a plurality of fins extending from the conducting plate.

The photovoltaic module further includes a junction box to gather electrical energy from the photovoltaic panel and the thermoelectric module, and output the electrical energy. The supporting frame is preferably made of aluminum, and the back sheet of the photovoltaic panel is preferably formed by a Tedlar® PVF film manufactured by Dupont, or a laminated film composite, TPT™, manufactured by Dupont.

Accordingly, the photovoltaic module according to the present invention can effectively reduce the operating temperature of the photovoltaic module so as to improve the efficiency of the photovoltaic module. In addition, the heat sink is attached to thermoelectric module to effectively increase the temperature gradient for the thermoelectric module to further improve the conversion efficiency from thermal energy to electrical energy. Hence, the total conversion efficiency from the solar energy to the electrical energy is further improved.

### BRIEF DESCRIPTION OF THE DRAWINGS

The foregoing aspects and many of the attendant advantages of this invention will be more readily appreciated as the same becomes better understood by reference to the following detailed description, when taken in conjunction with the accompanying drawings, wherein:

FIG. 1 illustrates a partial side view of a photovoltaic module having a thermoelectric module according to the present invention;

FIG. 2 illustrates an embodiment of a photovoltaic module having a thermoelectric module according to the present invention; and

FIG. 3 illustrates another embodiment of a photovoltaic module having a thermoelectric module according to the present invention.

### DETAILED DESCRIPTION OF THE PREFERRED EMBODIMENT

The following description is of the best presently contemplated mode of carrying out the present invention. This description is not to be taken in a limiting sense but is made merely for the purpose of describing the general principles of the invention. The scope of the invention should be determined by referencing the appended claims.

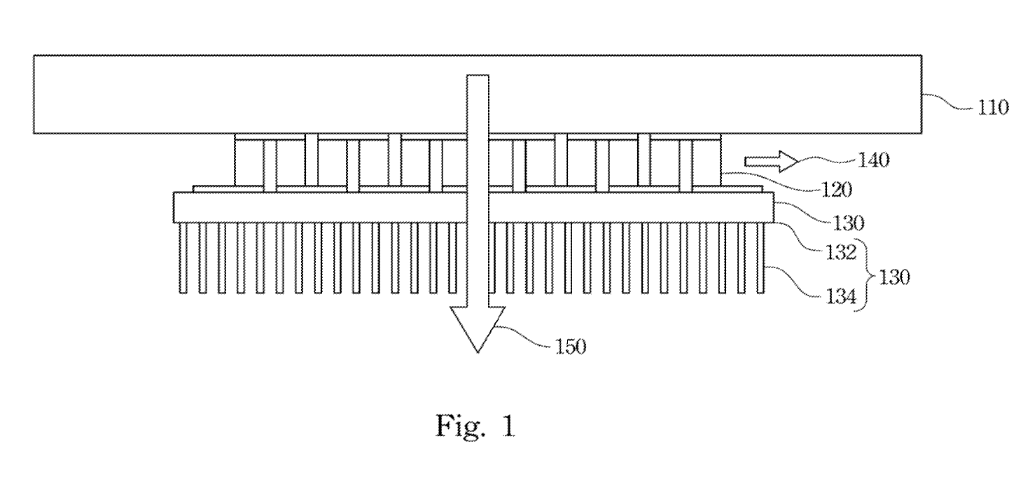

Refer to FIG. 1. FIG. 1 illustrates a partial side view of a photovoltaic module having a thermoelectric module according to the present invention. The photovoltaic module includes a photovoltaic panel 110, a thermoelectric module 120 coupled to the back side of the photovoltaic panel 110, and a heat sink 130 coupling to the thermoelectric module 120. Therefore, while the photovoltaic panel 110 is working, the solar energy is converted into electrical energy. In addition, the thermoelectric module 120 can effectively reduce the operating temperature of the photovoltaic panel 110 so as to improve the efficiency of the photovoltaic module. Furthermore, the heat sink 130 can further increase the temperature gradient for the thermoelectric module 120 so as to improve the conversion efficiency of the thermoelectric module 120. Therefore, the total conversion efficiency, i.e. the ratio of the generated electrical energy versus the received solar energy, is further improved. Arrow 140 illustrates the electrical energy output generated by the photovoltaic panel 110 and the thermoelectric module 120.

Furthermore, the thermoelectric cooling module 120 includes a hot side coupling to the backside of the photovoltaic panel 110 and a cold side coupling to the heat sink 130. The heat sink 130 is preferably formed by a conducting plate 132 to couple to the cold side of the thermoelectric cooling module 120, and a plurality of fins 134 extending from the conducting plate 132 to dissipate the heat to the environment. Therefore, the temperature of the photovoltaic module is reduced along the arrow 150. That is to say, the temperature gradient is therefore increased.

In addition, on the back side of the photovoltaic panel 110, the photovoltaic panel 110 preferably includes a back sheet formed by, but is not limited to a Tedlar® PVF film manufactured by Dupont, or a laminated film composite, TPT™, manufactured by Dupont, depending on the needs.

Refer to FIG. 2. FIG. 2 illustrates an embodiment of a photovoltaic module having a thermoelectric module according to the present invention. The photovoltaic module according to the present invention includes a photovoltaic panel 210 fixed in a supporting frame 240, a thermoelectric module 220 fixed on the back side of the photovoltaic panel 210 and a heat sink 230 fixed on the thermoelectric module 220. That is to say, the photovoltaic panel 210 is fixed to the hot side of the thermoelectric module 220, and the heat sink 230 is fixed to the cold side of the thermoelectric module 220. Both the thermoelectric module 220 and the photovoltaic panel 210 can output electrical energy to the junction box 250 fixed on the photovoltaic panel 210. Therefore, the conversion efficiency of the photovoltaic module is increased. In addition, the operating temperature of the photovoltaic module is effectively controlled. The total conversion efficiency from the solar energy to the electrical energy is improved.

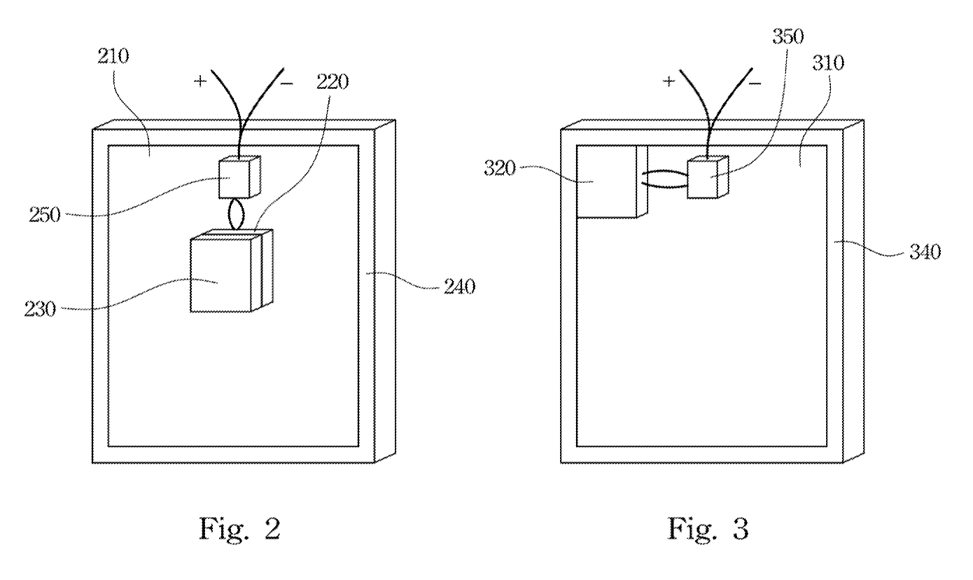

Refer to FIG. 3. FIG. 3 illustrates another embodiment of a photovoltaic module having a thermoelectric module according to the present invention. The photovoltaic module according to the present invention includes a photovoltaic panel 310 fixed in a supporting frame 340, and a thermoelectric module 320 fixed on the backside of the photovoltaic panel 310. It is worth noting that thermoelectric module 320 is fixed to the supporting frame 340 and the supporting frame 340 functions as a heat sink.

That is to say, the photovoltaic panel 310 is fixed to the hot side of the thermoelectric module 320, and the supporting frame 340 is fixed to the cold side of the thermoelectric module 320. Therefore, both of the thermoelectric module 320 and the photovoltaic panel 310 can output electrical energy to the junction box 350 fixed on the photovoltaic panel 310. The supporting frame 340 functions as a heat sink can further increase the temperature gradient for the thermoelectric module 320. Hence, the operating temperature of the photovoltaic module is further reduced. Accordingly, the conversion efficiency of the photovoltaic module is increased. The total conversion efficiency from the solar energy to the electrical energy is improved.

The supporting frame 340 can be made of a metal material, e.g. but is not limited to aluminum, aluminum alloy, or aluminum composite, with a good heat conducting property.

Accordingly, the photovoltaic module having the thermoelectric module according to the present invention can effectively reduce the operating temperature of the photovoltaic module so as to improve the efficiency of the photovoltaic module. The heat sink is attached to thermoelectric module to increase the temperature gradient thereof to further improve the conversion efficiency from thermal energy to electrical energy. Moreover, the supporting frame of the photovoltaic module can be used as the heat sink directly without additionally installing a heat sink device so that the supporting frame not only can support the photovoltaic module, but also can reduce the operating temperature of the photovoltaic panel. Hence, the total conversion efficiency from the solar energy to the electrical energy is improved.

As is understood by a person skilled in the art, the foregoing preferred embodiments of the present invention are illustrative of the present invention rather than limiting of the present invention. It is intended that various modifications and similar arrangements be included within the spirit and scope of the appended claims, the scope of which should be accorded the broadest interpretation so as to encompass all such modifications and similar structures.

What is claimed is:

1. A photovoltaic module, comprising:
a supporting frame;
a photovoltaic panel fixed on the supporting frame; and
a thermoelectric module fixed on the photovoltaic panel to reduce an operating temperature of the photovoltaic panel.

2. The photovoltaic module of claim 1, further comprising a heat sink fixed on the thermoelectric module.

3. The photovoltaic module of claim 2, wherein the thermoelectric module comprises a hot side to couple to the photovoltaic panel and a cold side to couple to the heat sink.

4. The photovoltaic module of claim 3, wherein the heat sink comprises a conducting plate to couple to the cold side of the thermoelectric module and a plurality of fins extending from the conducting plate.

5. The photovoltaic module of claim 1, wherein the supporting frame functions as a heat sink and the thermoelectric module is fixed to the supporting frame.

6. The photovoltaic module of claim 5, wherein the thermoelectric module comprises a hot side to couple to the photovoltaic panel and a cold side to couple to the supporting frame.

7. The photovoltaic module of claim 1, wherein the supporting frame is a material selected from a group of aluminum, aluminum alloy and aluminum composite.

8. The photovoltaic module of claim 1, further comprising a junction box to gather electrical energy from the photovoltaic panel and the thermoelectric module and output the electrical energy.

9. The photovoltaic module of claim 1, wherein the photovoltaic panel comprises a back sheet on a backside of the photovoltaic panel.

10. A photovoltaic module, comprising:
a supporting frame;
a photovoltaic panel fixed on the supporting frame;
a thermoelectric module fixed on the photovoltaic panel to reduce an operating temperature of the photovoltaic panel;
a heat sink fixed on the thermoelectric module, wherein the thermoelectric module comprises a hot side to couple to the photovoltaic panel and a cold side to couple to the heat sink; and
a junction box to gather electrical energy from the photovoltaic panel and the thermoelectric module and output the electrical energy,
wherein the heat sink comprises a conducting plate to couple to the cold side of the thermoelectric module and a plurality of fins extending from the conducting plate, and the photovoltaic panel comprises a back sheet on a backside of the photovoltaic panel.
